(19) United States
(12) Patent Application Publication
(10) Pub. No.: US 2019/0062909 A1
(43) Pub. Date: Feb. 28, 2019

(54) INJECT ASSEMBLY FOR EPITAXIAL DEPOSITION PROCESSES

(71) Applicant: Applied Materials, Inc., Santa Clara, CA (US)

(72) Inventors: Shinichi OKI, Chiba-Ken (JP); Yuji AOKI, Yokohama-Shi Kanagawa-Ken (JP); Yoshinobu MORI, Ohmura-shi (JP)

(21) Appl. No.: 16/031,691

(22) Filed: Jul. 10, 2018

Related U.S. Application Data
(60) Provisional application No. 62/550,048, filed on Aug. 25, 2017.

(51) Int. Cl. C23C 16/455; C23C 16/458; C23C 16/44

(52) U.S. Cl. CPC C23C 16/45502; C23C 16/4584; C23C 16/45578; C23C 16/4404; C23C 16/45574

(57) ABSTRACT

In one embodiment, a gas introduction insert includes a gas distribution assembly having a body, a plurality of gas injection channels formed within the gas distribution assembly, at least a portion of the plurality of gas injection channels being adjacent to a blind channel formed in the gas distribution assembly, and a rectification plate bounding one side of the plurality of gas injection channels and the blind channel, the rectification plate including a non-perforated portion corresponding to the position of the blind channel.

### CROSS-REFERENCE TO RELATED APPLICATION

This application claims priority to U.S. Provisional Patent Application Ser. No. 62/550,048, filed Aug. 25, 2017, which is hereby incorporated by reference herein.

### BACKGROUND

### Field

Embodiments of the present disclosure generally relate to the providing of precursor gases for performing a semiconductor device fabrication process. More specifically, embodiments of the present disclosure generally relate to the providing of precursor gases used in deposition and etch reactions performed on a semiconductor substrate, such as an epitaxial deposition process or other chemical vapor deposition process.

### Description of the Related Art

Epitaxial growth of silicon and/or germanium-containing films on substrates has become increasingly important due to new applications for advanced logic and DRAM devices and semiconductor power devices, among other semiconductor devices. A key requirement for some of these applications is the uniformity of the film thickness of a grown or deposited layer across the substrate surface. Typically, film thickness uniformity is related to the uniformity of the gas flow rate across the substrate.

However, deposition or carrier gas flows (i.e., velocity) in some conventional chambers are not uniform, which may result in non-uniformity of the thickness of the grown or deposited layer across the substrate surface. In some cases, the substrate may be rendered unusable when the non-uniformity exceeds a certain limit.

Therefore, there is a need in the art for an apparatus and method to minimize a difference in precursor gas flows or velocities flowing during an epitaxial growth or deposition process.

### SUMMARY

Embodiments described herein relate to an apparatus and to methods for delivering a process gas to a processing region within a chamber to form a film layer across an exposed surface of the substrate having a substantially equal thickness.

In one embodiment, a gas introduction insert includes a gas distribution assembly having a body, a plurality of gas injection channels formed within the gas distribution assembly, at least a portion of the plurality of gas injection channels being adjacent to a blind channel formed in the gas distribution assembly, and a rectification plate bounding one side of the plurality of gas injection channels and the blind channel, the rectification plate including a non-perforated portion at a position corresponding to the position of the blind channel in the gas distribution assembly.

In another embodiment, a gas introduction insert for a reaction chamber is provided, the gas introduction insert including an injection block having at least one inlet to deliver a precursor gas from at least two gas sources to a plurality of plenums, a gas distribution assembly coupled to the injection block, a rectification plate bounding one side of the plurality of plenums, the rectification plate including a non-perforated portion on opposing ends thereof, and a plurality of gas injection channels formed within a body of the gas distribution assembly, at least a portion of the plurality of gas injection channels being adjacent to a blind channel formed in the body corresponding to positions of the non-perforated portion of the rectification plate.

In another embodiment, a method of delivering a precursor gas to a processing region in a chamber is provided. The method comprises providing a precursor gas to a rectification plate having a non-perforated region and a perforated region in fluid communication with a plurality of gas injection channels defining a gas injection portion, at least a portion of the plurality of gas injection channels being positioned adjacent to a blind channel, and flowing the precursor gas toward the non-perforated region and through openings in the perforated region of the rectification plate and into the plurality of gas injection channels, wherein a length of the rectification plate is greater than a length of the gas injection portion, and wherein the length of the gas injection portion is substantially equal to a diameter of a substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a cross-sectional view illustrating one embodiment of an epitaxial growth apparatus.

FIG. 2 is an exploded isometric view illustrating the reaction chamber of the epitaxial growth apparatus of FIG. 1.

FIG. 3 is an exploded isometric view illustrating the reaction chamber of the epitaxial growth apparatus of FIG. 1.

FIG. 4 is a schematic top view of a portion of an epitaxial growth apparatus in cross-section.

FIG. 5 is an isometric view of a gas distribution assembly coupled to the processing volume of a reaction chamber.

To facilitate understanding hereof, identical reference numerals have been used, wherever possible, to designate identical elements that are common to different ones of the figures. It is also contemplated that elements disclosed in one embodiment may be beneficially utilized on other embodiments without a specific recitation in a different embodiment.

### DETAILED DESCRIPTION

The present disclosure provides a film layer forming method using epitaxial growth and an epitaxial growth apparatus, which can achieve a stable and high growth rate of an epitaxial film layer with high film thickness uniformity across the growth surface of the substrate. More specifically, the present disclosure describes chamber components for an epitaxial growth apparatus that enable the film forming method. Exemplary chamber components and improvements therein have resulted in enhancement of the film thickness uniformity and growth rate of the epitaxial layer formed on the growth surface of a substrate resulting in higher throughput of substrates having a more uniform film layer epitaxially grown thereof and a reduction of the defects in the epitaxially grown film.

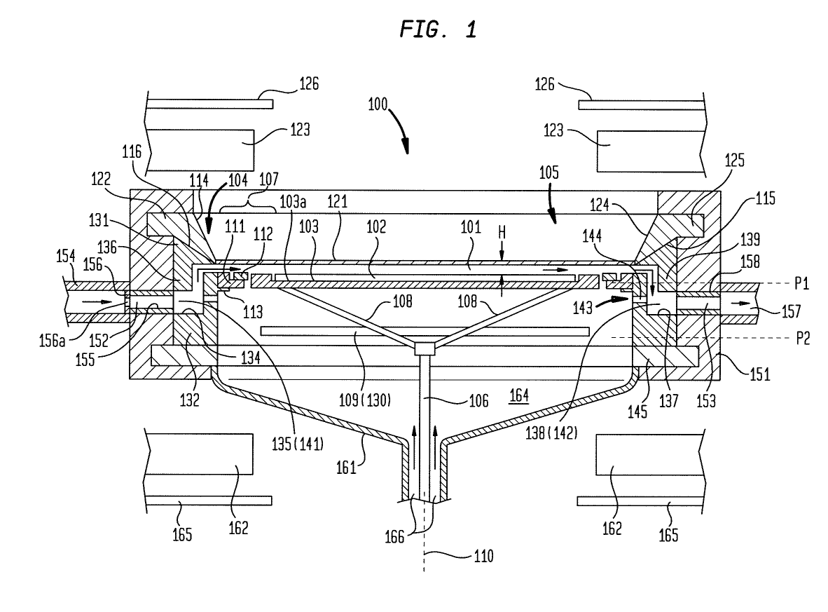

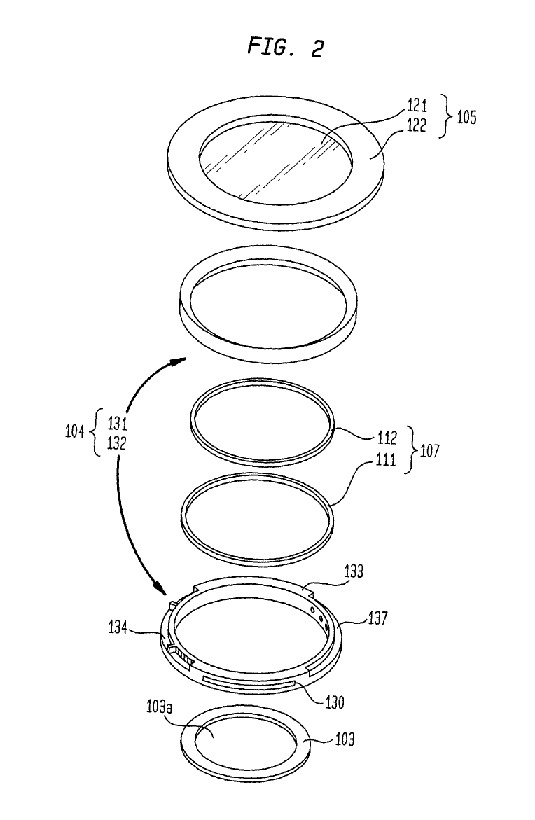

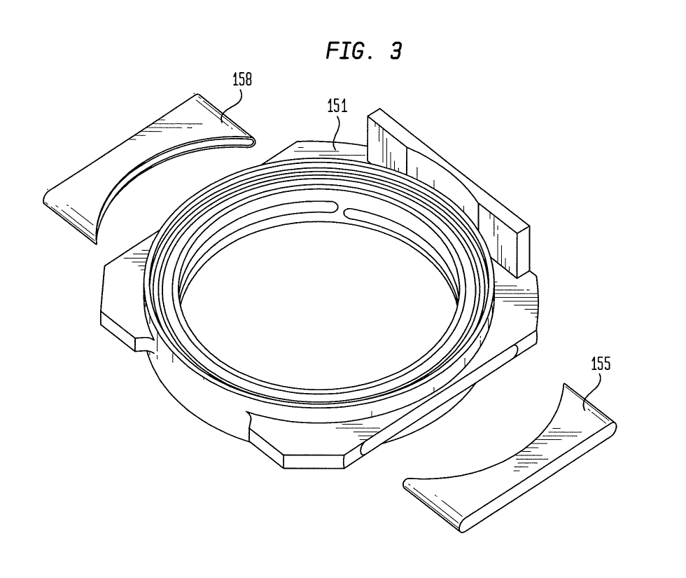

Initially herein, the configuration of an epitaxial growth apparatus 100 according to one embodiment of the present disclosure is described. FIG. 1 is a cross-sectional view illustrating the configuration of the epitaxial growth apparatus 100. FIG. 2 is an exploded isometric view illustrating the configuration of portions of a reaction chamber 101 of the epitaxial growth apparatus 100. FIG. 3 is an exploded isometric view illustrating the outer configuration of the reaction chamber 101 of the epitaxial growth apparatus 100.

The epitaxial growth apparatus 100 is a film forming apparatus that enables, for example, a film layer of silicon to epitaxially grow on a substrate 102.

The epitaxial growth apparatus 100 includes a reaction chamber 101. The reaction chamber 101 includes a susceptor 103 on which the substrate 102 is mounted for growth of the epitaxial film layer thereon, a surrounding body 104, and a ceiling 105.

The susceptor 103 is a plate-like member having a circular annular shape when seen from above and has an outer circumference slightly larger than that of the substrate 102. The susceptor 103 is provided with a recess portion 103a into which the substrate 102 is mounted for epitaxial growth of the film layer thereon. The susceptor 103 is supported by a susceptor support 106 having plural arms 108 extending upwardly and radially therefrom to the underside of the susceptor 103.

The plural arms 108 of the susceptor support 106 are configured, along with the susceptor support 106, to move the susceptor 103 upwardly and downwardly while supporting the susceptor 103. The susceptor support 106 and arms 108 are configured to rotate the susceptor 103 about a longitudinal axis 110 thereof. The position in the chamber of the surface of the susceptor 103 on which the substrate 102 is mounted ranges from a film-forming plane P1 at which a film is grown on a substrate 102 located on the susceptor 103 to a substrate transfer plane P2 at which the substrate 102 is loaded into and retracted from the epitaxial growth apparatus 100 through a valved opening 109 in the wall of the epitaxial growth apparatus 100. The susceptor support 106 is configured to enable the susceptor 103, and thus substrate 102, to rotate by rotating about the longitudinal axis 110 of the susceptor support 106 while it is located at the film-forming plane P1.

An annular susceptor ring assembly 107 is disposed around the susceptor 103 when the susceptor 103 is located at the film-forming plane P1. Although the details thereof will be described later herein, the susceptor ring 107 assembly includes a first ring 111, and a second ring 112 located on the first ring 111. The susceptor ring assembly 107 is supported in the reaction chamber 101 by a flange portion 113 extending inwardly from the inner side wall of the supporting body 104 of the reaction chamber 101.

The ceiling portion 105 includes a ceiling plate 121 and a support 122 extending around, and supporting, the ceiling plate 121. The ceiling plate 121 is transparent to radiant energy in in the visible spectrum as well as wavelengths near the visible spectrum. The ceiling plate 121 is configured to allow radiant energy to pass therethrough and heat the substrate 102 within the reaction chamber 101 by transmitting energy from heating devices 123 (for example, halogen lamps) disposed above the ceiling plate 121 and below an upper reflector 126. That is, the epitaxial growth apparatus 100 according to this embodiment is a cold wall type epitaxial growth apparatus. In this embodiment, the ceiling plate 121 is formed of transparent quartz.

The support 122 supporting the ceiling plate 121 has an annular shape and it surrounds the ceiling plate 121. The ceiling plate 121 is fixed to the end of the support 122 in proximity to the substrate 102 at the base of an inner frustoconical wall 124 of the support 122. An example of the fixing method is a welding method.

The side support body 104 includes an upper ring 131 and a lower ring 132. The flange portion 113 extends inwardly of the chamber volume from the inner circumference of the lower ring 132. A substrate transfer port 130 extends through the lower ring 132 at a location below the flange portion 113. The upper ring 131 has an outer sloped portion 114 corresponding to an inner sloped portion 115 interfacing with a protruded portion 125 of the support 122 . The support 122 is disposed on a sloped portion 116 of the upper ring 131.

Along the top surface of the lower ring 132, a part along the outer circumference thereof forms a mounting surface 133 (shown in FIG. 2) on which the upper ring 131 is mounted. A first recessed portion 134 is formed in the lower ring 132 by providing a cutout region in the lower ring 132. That is, the first recessed portion 134 is a concave portion formed in a portion of the top surface of the lower ring 132. In the upper ring 131, a first protruding portion 136 is formed at the position corresponding to the first recessed portion 134 in the lower ring 132 so as to correspond to the shape of the first recessed portion 134 and to form a gap 135 between the first recessed portion 134 and the first protruding portion 136. The gap 135 between the first protruding portion 136 and the first recessed portion 134 serves as a reactant gas supply path 141 (supply path). Further details of the reactant gas supply path 141 will be described later herein.

In the region opposed to the first recessed portion 134 of the lower ring 132, a part of the outer circumferential portion of the top surface of the lower ring 132 is cut out to form a second recessed portion 137. In the upper ring 131, a second protruding portion 139 is formed at the position corresponding to the second recessed portion 137 so as to correspond to the shape of the second recessed portion 137 and to form a gap 138 between the second recessed portion 137 and the second protruding portion 139. A gas discharge path 142 is formed in the gap 138 between the second recessed portion 137 and the second protruding portion 139 of the upper ring 131.

In this way, the reactant gas supply path 141 and the gas discharge path 142 are diagonally opposed across the processing region of the reaction chamber 101, and the reactant gas introduced into the reaction chamber 101 from the gas supply path 141 flows over the substrate 102 in a horizontal direction (orthogonal to the longitudinal axis 110).

A purge hole 144, through which a purge gas is discharged, is formed in a wall surface 143 of the second protruding portion 137 of the lower ring 132. The purge hole 144 is formed below the flange portion 113. The purge hole 144 communicates with the gas discharge path 142 and thus both a reactant gas and a purge gas can be discharged through the gas discharge path 142.

An annular platform 145 is provided below the bottom surface side of the lower ring 132 of the body 104 and the body 104 is located on the platform 145. The platform 145 may located within an annular clamping portion 151.

The annular clamping portion 151 is disposed on the outer circumference of the ceiling portion 105, the side wall 104, and the platform 145. The annular clamping portion 151 clamps and supports the ceiling portion 105, the side wall 104, and the platform 145. The clamping portion 151 is provided with a supply-side communication path 152 communicating with the reactant gas supply path 141 and a discharge-side communication path 153 communicating with the gas discharge path 142. A gas introduction insert 155 is provided in the supply-side communication path 152. A gas discharge insert 158 is provided in the discharge-side communication path 153.

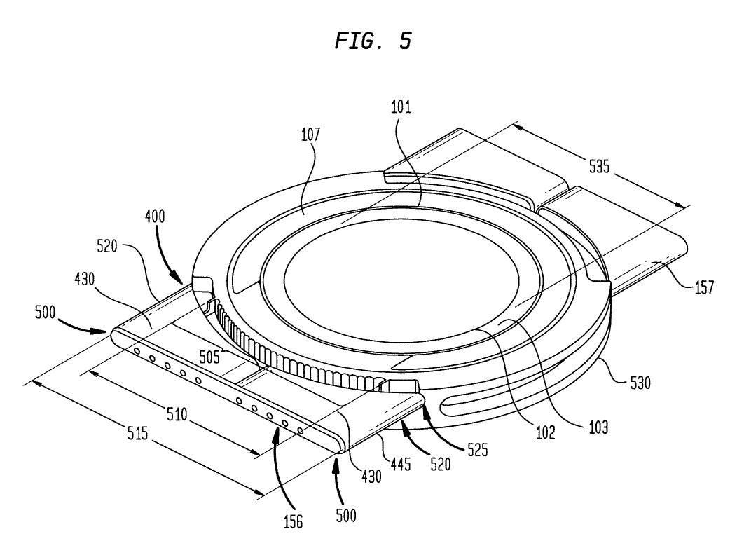

A reactant gas introducing portion 154 is disposed outside the clamping portion 151, and the reactant gas introducing portion 154 and the supply-side communication path 152 are in fluid communication with each other. In this embodiment, a first source gas and a second source gas are introduced from the reactant gas introducing portion 154. The second source gas also serves as a carrier gas. A mixture of three or more types of gases may be used as the reactant gas. A rectification plate 156 is disposed in the reactant gas introducing portion 154 where it joins the supply-side communication path 152, The rectification plate 156 is provided with plural openings 156a (FIG. 5) extending therethrough along a straight line path generally parallel to the upper surface of the susceptor 103, and the first source gas and the second source gas are mixed and rectified by causing the reactant gas to pass through the openings 156a. A gas discharge portion 157 is disposed exteriorly of the clamping portion 151. The gas discharge portion 157 is disposed at a position facing the reactant gas introducing portion 154 with the center of the reaction chamber 101 interposed therebetween.

A chamber bottom portion 161 is disposed in the lower part of the inner circumference side of the platform 145. Another heating device 162 and a lower reflector 165 are disposed outside the chamber bottom portion 161 so the substrate 102 can also be heated from the lower side.

The center of the chamber bottom portion 161 is provided with a purge gas introducing portion 166 along the longitudinal axis 110 of the susceptor support 106. The purge gas is introduced into a lower reaction chamber part 164 formed by the chamber bottom portion 161, the lower ring 132, and the platform 145 from a purge gas source (not shown). The purge hole 144 is also in fluid communication with the lower reaction chamber part 164 through the lower inner volume of the chamber 101.

A film forming method using the epitaxial growth apparatus according to this embodiment will be described below.

First, the susceptor 103 is moved to the substrate-carrying plane P2, a substrate 102 is transferred through the valved opening 109 and the substrate transfer port 130, and the susceptor 103 with the substrate thereon is moved to the film-forming plane P1. For example, a silicon substrate with a diameter of 200 mm is used as the substrate 102. Then, the substrate is heated from a standby temperature (for example, 800° C.) to a growth temperature (for example, 1,100° C.) by the use of the heating devices 123 and 162. A purge gas 166 (for example, hydrogen) is introduced into the lower reaction chamber part 164 from a purge gas supply. The reactant gas (for example, trichlorosilane as the first source gas and hydrogen as the second source gas) is introduced into the reaction chamber 101 through the reactant gas supply path 141 from the reactant gas introducing portion 154. The reactant gas forms a boundary layer on the surface of the substrate 102 and a reaction occurs in the boundary layer. Accordingly, a silicon film is formed on the substrate 102. The reactant gas is discharged from the gas discharge path 142 communicating with the reaction chamber 101. The purge gas is discharged to the gas discharge path 142 through the purge hole 144. After the epitaxial growth, the temperature of the substrate 102 returns to the standby temperature and the substrate 102 is taken out of the chamber 101 and is moved to another chamber of a semiconductor manufacturing apparatus.

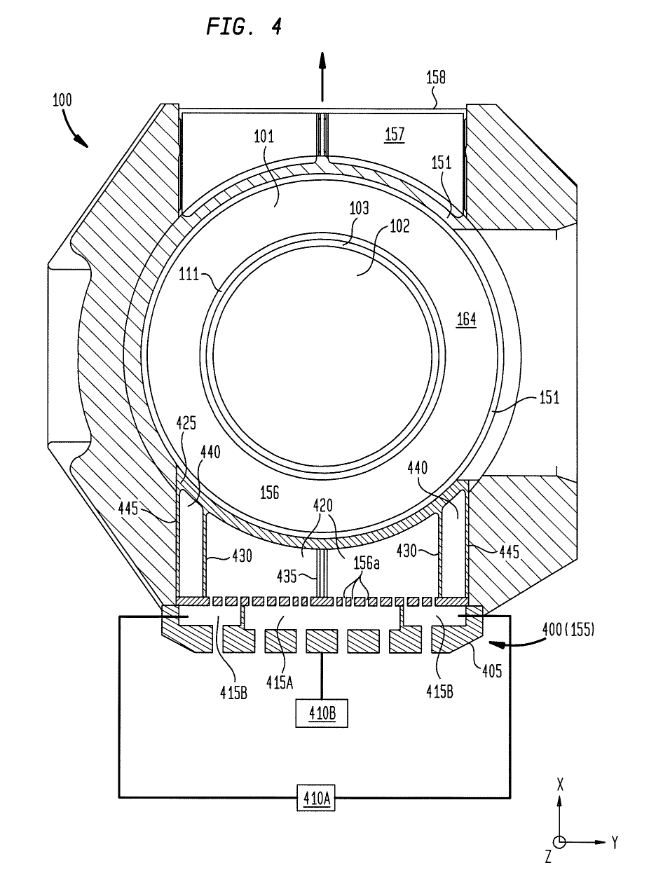

FIG. 4 is a schematic top view of a portion of an epitaxial growth apparatus 100 in cross-section. The gas introduction insert 155, depicted in FIG. 4 as a gas distribution assembly 400, is shown coupled to the annular clamping portion 151. The gas distribution assembly 400 includes an injection block 405 coupled to one or more gas sources 410A and 410B. The injection block 405 includes one or more plenums disposed upstream of the openings 156a of the rectification plate 156, such as inner plenum 415A and outer plenums 415B.

The gas sources 410A, 410B may include silicon precursors such as silanes, including silane (SiH₄), disilane (Si₂H₆,), dichlorosilane (SiH₂Cl₂), hexachlorodisilane (Si₂Cl₆), dibromosilane (SiH₂Br₂), higher order silanes, derivatives thereof, and combinations thereof. The gas sources 410A, 410B may also include germanium containing precursors, such as germane (GeH₄), digermane (Ge₂H₆), germanium tetrachloride (GeCl₄), dichlorogermane (GeH₂Cl₂), derivatives thereof, and combinations thereof. The silicon and/or germanium containing precursors may be used in combination with hydrogen chloride (HCI), chlorine gas (Cl₂), hydrogen bromide (HBr), and combinations thereof. The gas sources 410A, 410B may include one or more of the silicon and germanium containing precursors present in one or both of the gas sources 410A, 410B. For example, the gas source 410A, which may be in communication with the outer plenums 415B, may include precursor materials, such as hydrogen gas (H₂) or chlorine gas (Cl₂), while gas source 410B may include silicon and/or germanium containing precursors, derivatives thereof, or combinations thereof.

The precursor materials from the gas sources 410A, 410B are delivered to the inner plenum 415A and the outer plenums 415B. The precursor materials enter the processing volume of the reaction chamber 101 through the inner plenum 415A and the outer plenums 415B, through openings 156a in the rectification plate 156, and one or more gas injection channels 420 formed in a body 425 of the gas distribution assembly 400.

In the plan view shown in FIG. 4, the one or more gas injection channels 420 are bounded by outer walls 430, the rectification plate 156, and a central partition 435. Blind channels 440 are shown on the outside of the outer walls 430 where the openings 156a are not formed in the rectification plate 156 (i.e., a non-perforated portion of the rectification plate 156). The body 425 also includes side plates 445 that, along with the non-perforated portion of the rectification plate 156 and the outer walls 430, bound the blind channels 440. The blind channels 440 as well as the one or more gas injection channels 420 may be in fluid communication with the processing volume of the reaction chamber 101 (e.g., the blind channels 440 are open on one end thereof). However, no precursor gases flow from the injection block 405 to the processing volume of the reaction chamber 101 through the blind channels 440. The precursor gas(es) introduced by the source 410A initially enters plenums 415B, from which it flows into plenum 410. The precursor gas(es) introduced by the source 410B initially enters plenum 415A, from which it flows into plenum 410 to be intermixed with the precursor gas from source 410A. The precursor gases then flow over the substrate 102 and exit the processing volume of the reaction chamber 101 via the gas discharge portion 157. At least the body 425 of the gas distribution assembly 400, which includes the outer walls 430 and the rectification plate 156 may be fabricated from a quartz material.

FIG. 5 is an isometric view of the gas distribution assembly 400 coupled to the processing volume of the reaction chamber 101. A substrate 102 is shown on the susceptor 103, and the annular susceptor ring 107 substantially surrounds the susceptor 103. In some embodiments, the annular susceptor ring 107 comprises a heat shield.

A gas injection portion 505 of the gas distribution assembly 400, the width which through which gas is introduced into chamber 101 defined by a distance 510 between the outer walls 430 of the gas distribution assembly 400, is shown in FIG. 5.

In some embodiments, the distance 510 is less than a dimension 515 of the gas distribution assembly 400 (i.e., length from one end plate 445 to another end plate 445). Outer portions 520 of the gas distribution assembly 400, which include the blind channels 440, may be used to occupy an existing opening 525 in a body 530 of the reaction chamber 101, thereby allowing the gas distribution assembly 400 to be customized to be retrofit into an existing chamber. In some embodiments, the gas distribution assembly 400 is a replaceable liner assembly, and the gas distribution assembly 400 may be replaced as necessary. The outer portions 520, although not necessary for gas flow as described above, may be utilized to occupy the existing opening 525 in order to maintain vacuum, among other attributes.

In some embodiments, the distance 510 of the gas injection portion 505 of the gas distribution assembly 400 is substantially equal to a diameter 535 of the substrate 102. For example, if the substrate 102 has a diameter of 200 millimeters (mm), the distance 510 of the gas injection portion 505 of the gas distribution assembly 400 is substantially equal to 200 mm. The term “substantially equal” may be defined as +/− about 3 mm, or less, based on a 200 mm substrate.

The reasons for this proportionality are numerous and are based on observations and simulations. It has been observed that the processing volume of the reaction chamber 101 is cylindrically shaped while the gas injection portion 505 of the gas distribution assembly 400 is rectangular. In conventional gas distribution assemblies where the volume of the gas distribution assembly 400 having the blind channels 440 is unmodified to allow gas to also flow in those locations and there are openings 156a across the entire length of the rectification plate 156, resulting in the gas injection portion being greater than the distance 510 as well as the greater than the diameter 535 of the substrate 102, and the gas flow tends to have a higher velocity at the ends of the gas injection portion as compared to a center of the gas injection portion. This relative higher velocity at the edges of the gas distribution assembly is attributed to a decrease in cross-sectional area at the edges thereof which increases velocity therein. This non-uniform gas flow leads to non-uniform film growth on a substrate. For example, while flow rates may be controlled in the conventional gas distribution assemblies, the control of flow rate has little impact on the film growth on the edges of a substrate. This non-uniform gas flow has been shown to produce a thickness non-uniformity that is about +/−1.0% across the substrate, which is outside of specifications for some semiconductor device applications.

In contrast, utilizing the gas distribution assembly 400 as disclosed herein with the distance 510 of the gas injection portion 505 of the gas distribution assembly 400 that is substantially equal to the diameter 535 of the substrate 102, improved thickness non-uniformity to about +/− 0.6% across the substrate 102.

Tests performed on the gas distribution assembly 400 as disclosed herein confirmed a substantially uniform flow velocity across the gas injection portion 505 (e.g., along the distance 510). For example, a velocity across the gas injection portion 505 varies by +/−0.5 meters/second as compared to velocities of a conventional gas distribution assembly that vary by +/−1.5 meters/second. This reduced variation in flow velocity across the gas injection portion 505 of the gas distribution assembly 400 as disclosed herein results in the improved thickness uniformity as discussed above.

While the foregoing is directed to embodiments of the present disclosure, other and further embodiments of the disclosure may be devised without departing from the basic scope thereof, and the scope thereof is determined by the claims that follow.

1. A gas introduction insert comprising:
a gas distribution assembly having a body;
a plurality of gas injection channels formed within the gas distribution assembly, at least a portion of the plurality of gas injection channels being adjacent to a blind channel formed in the gas distribution assembly; and
a rectification plate bounding one side of the plurality of gas injection channels and the blind channel, the rectification plate including a non-perforated portion at a position corresponding to the position of the blind channel in the gas distribution assembly.

2. The gas introduction insert of claim 1, wherein the blind channel is positioned at an end of the gas distribution assembly.

3. The gas introduction insert of claim 1, wherein the blind channel comprises two blind channels, and the rectification plate includes the non-perforated portion at opposing ends thereof.

4. The gas introduction insert of claim 1, wherein a length of the rectification plate is greater than a length of a gas injection portion of the gas distribution assembly.

5. The gas introduction insert of claim 4, wherein the length of the gas injection portion of the gas distribution assembly is substantially equal to a diameter of a substrate.

6. The gas introduction insert of claim 1, wherein the blind channel is open on one end thereof.

7. The gas introduction insert of claim 1, wherein each of the plurality of gas injection channels are bounded by the rectification plate, an outer wall, and a central partition.

8. The gas introduction insert of claim 7, wherein the blind channel is bounded by the rectification plate, the outer wall and an end wall of the gas distribution assembly.

9. A gas introduction insert for a reaction chamber, the gas introduction insert comprising:
an injection block having at least one inlet to deliver a precursor gas to a plurality of plenums from at least two gas sources;
a gas distribution assembly coupled to the injection block;
a rectification plate bounding one side of the plurality of plenums, the rectification plate including a non-perforated portion on opposing ends thereof; and
a plurality of gas injection channels formed within a body of the gas distribution assembly, at least a portion of the plurality of gas injection channels being adjacent to a blind channel formed in the body corresponding to positions of the non-perforated portion of the rectification plate.

10. The gas introduction insert of claim 9, wherein each of the plurality of gas injection channels are bounded by the rectification plate, an outer wall, and a central partition.

11. The gas introduction insert of claim 10, wherein the blind channel is bounded by the rectification plate, the outer wall and an end wall of the gas distribution assembly.

12. The gas introduction insert of claim 9, wherein a length of the rectification plate is greater than a length of a gas injection portion of the gas distribution assembly.

13. The gas introduction insert of claim 12, wherein the length of the gas injection portion of the gas distribution assembly is substantially equal to a diameter of a substrate.

14. The gas introduction insert of claim 9, wherein the blind channel is open on one end thereof.

15. The gas introduction insert of claim 9, wherein the blind channel is positioned at an end of the gas distribution assembly.

16. The gas introduction insert of claim 9, wherein the blind channel comprises two blind channels, and the rectification plate includes the non-perforated portion at opposing ends thereof.

17. A method of delivering a precursor gas to a processing region in a chamber, comprising:
providing a precursor gas to a rectification plate having a non-perforated region and a perforated region in fluid communication with a plurality of gas injection channels defining a gas injection portion, at least a portion of the plurality of gas injection channels being positioned adjacent to a blind channel; and
flowing the precursor gas toward the non-perforated region and through openings in the perforated region of the rectification plate and into the plurality of gas injection channels, wherein a length of the rectification plate is greater than a length of the gas injection portion, and wherein the length of the gas injection portion is substantially equal to a diameter of a substrate.

18. The method of claim 17, wherein the blind channel is in fluid communication with the processing region.

19. The method of claim 17, wherein the precursor gas exits the plurality of gas injection channels in a flow path is substantially parallel to a plane of a major surface of the substrate.

20. The method of claim 17, wherein a velocity of the precursor gas exiting the plurality of gas injection channels is substantially equal across a length of the gas injection portion.
